(19) United States
(12) Patent Application Publication
(10) Pub. No.: US 2025/0004383 A1
(43) Pub. Date: Jan. 2, 2025

(54) METHOD OF PRODUCING MASK DATA FOR SEMICONDUCTOR DEVICE MANUFACTURING

(71) Applicant: Taiwan Semiconductor Manufacturing Co., Ltd., Hsinchu (TW)

(72) Inventors: Kenji YAMAZOE, Hsinchu (TW); Chih-Shiang CHOU, Hsinchu (TW)

(21) Appl. No.: 18/346,113

(22) Filed: Jun. 30, 2023

(51) Int. Cl. G03F 7/00; G03F 1/70; H01L 21/033

(52) U.S. Cl. CPC G03F 7/705; G03F 1/70; H01L 21/0337

(57) ABSTRACT

A process for forming a photolithography mask includes generating a sub-resolution assist feature (SRAF) pattern from a blank mask layout based on a target layout. The SRAF pattern can be generated using an iterative process including finding the gradient of a cost function. A main pattern can be generated simultaneously with the SRAF pattern or after generation of the SRAF pattern.

### BACKGROUND

The electronics industry has experienced an ever-increasing demand for smaller and faster electronic devices to support a greater number of increasingly complex and sophisticated functions. Accordingly, there is a continuing trend in the semiconductor industry to manufacture low-cost, high-performance, and low-power integrated circuits (ICs). Thus far, these goals have been achieved in large part by scaling down semiconductor IC dimensions (e.g., minimum feature size) and thereby improving production efficiency and lowering associated costs. However, such scaling down has also introduced increased complexity to the semiconductor manufacturing process. Thus, the realization of continued advances in semiconductor ICs and devices calls for similar advances in semiconductor manufacturing processes and technology.

As merely one example, scaling down of IC dimensions has been achieved by extending the usable resolution of a given lithography generation by the use of one or more resolution enhancement technologies (RETs), such as phase shift masks (PSMs), off-axis illumination (OAI), optical proximity correction (OPC), and insertion of sub-resolution assist features (SRAFs) into a design layout. Several SRAF insertion or placement techniques have been proposed. Some of them, being rule-based, have relatively short turn-around time but far-from-ideal accuracy. Some of them use numerous iterations of mask optimization to achieve outstanding accuracy but take a long time for each SRAF insertion exercise. Thus, existing techniques have not proved entirely satisfactory in all respects.

### BRIEF DESCRIPTION OF THE SEVERAL VIEWS OF THE DRAWINGS

FIG. 1 is a schematic illustration of components of an exposure tool, in accordance with some embodiments.

FIG. 2A-2N is an illustration of seed maps, layouts, illumination, schematic view of gradient descent optimization concept, and examples of cost in accordance with some embodiments.

FIG. 3 is an illustration of a process for producing a pattern for a mask, in accordance with some embodiments.

FIG. 4 is an illustration of a process for producing a pattern for a mask, in accordance with some embodiments.

FIG. 5 is an illustration of a process for producing a pattern for a mask, in accordance with some embodiments.

FIG. 6 is an illustration of optimized mask patterns, in accordance with some embodiments.

FIG. 7 includes plots of process windows, in accordance with some embodiments.

FIG. 8 is a flow diagram of a method for generating a pattern for a photolithography mask, in accordance with some embodiments.

FIG. 9 is a flow diagram of a method for processing a semiconductor wafer, in accordance with some embodiments.

FIGS. 10A-10E are cross-sectional views of a wafer at various processing stages, in accordance with some embodiments.

FIG. 11A is an illustration of a computing system, in accordance with some embodiments.

FIG. 11B is an illustration of a computing system, in accordance with some embodiments.

FIG. 12 is an illustration of a photolithography mask and a semiconductor wafer, in accordance with some embodiments.

FIG. 13 is a flow diagram of a method for preparing a mask for use in a photolithographic patterning of a layer on a substrate, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure generate the pattern layout for a photolithography mask in an effective and efficient manner. The SRAF pattern is generated from a blank mask layout without a previously generated main pattern. Instead, the SRAF pattern is based on a target pattern corresponding to a pattern desired to be formed on a device. The SRAF pattern is generated in iterations. The gradient of a cost function is monitored between iterations until a SRAF pattern has been found that results in optimum function. The main pattern of the mask can be formed simultaneously with the SRAF pattern or after formation of the SRAF pattern. OPC fine-tuning can then be performed. After the SRAF pattern and main patterns have been determined, the photolithography mask can be formed including the determined SRAF and main patterns. This process results in higher quality photolithography masks. This further results in integrated circuits with higher yields and fewer defects.

The present disclosure is generally related to generating pattern of a photolithography mask used in a photolithography process. The pattern of the photolithography mask includes a main pattern. During the photolithography process, a light source illuminates the photolithography mask to transfer the main pattern of the photolithography mask into a substrate. The transferred pattern forms a target pattern on the substrate (or a layer on the substrate e.g., a photoresist layer). The target pattern determines elements of a semiconductor device on the substrate (e.g., a silicon wafer). Due to an optical proximity effect, the shape of the target pattern is not the same as the main pattern. The optical proximity effect results in variations of the linewidth and shape of the target pattern as a function of the proximity to the photolithography mask and the light source due to diffraction of the light waves.

There are some techniques to compensate for the differences between the main pattern and the target pattern due to the optical proximity effect (e.g., resolution enhancement technologies (RETs)). Optical proximity correction (OPC) is a technique which is used to add some features to the main pattern to compensate the optical proximity effect. Another technique is placing the SRAF around the main pattern to enhance the resolution of the target pattern by compensating the optical proximity effect. SRAFs are features that are small enough not to be printed on the substrate in the photolithography process (e.g., below the resolution limit of the photolithography apparatus), but are so shaped and placed on the photolithography mask to improve the quality of the target pattern (e.g., a lithography image) on the substrate.

In general, the SRAF seed map is generated based on the main pattern and the target pattern. In some techniques, the SRAF seed map is generated based on the main and target patterns, and the OPC is added to the photolithography mask after placing the SRAF. In this condition, the main pattern is needed to generate the SRAF seed map. However, the main pattern depends on the SRAF. Thus, the main pattern is estimated before calculating the SRAF seed map, which consequently may reduce the accuracy of the photolithography pattering prediction. In addition, the OPC is added after placing the SRAF, thus the position of the SRAF may not be optimized when the OPC is added. As a result, a model which is used to generate SRAF seed map and determine the location of the SRAF on the photolithography mask, may not be accurate to enhance the resolution of the target pattern.

The present disclosure is directed to a method of, generating the SRAF and the main pattern based on the target pattern. Thus, the SRAF seed map is not generated based on the main pattern, but both the SRAF and the main pattern are generated together based on the target pattern. This method overcomes inaccuracy of the generating the SRAF seed map by having the main pattern, due to the dependency of the main pattern to the SRAF seed map. In addition, the disclosed method includes placing the SRAF on the photolithography mask based on an estimation of the light transmission, while the photolithography mask is blank. Hence, the position of the SRAF as well as the main pattern are estimated simultaneously. In various embodiments of the present disclosure, the generation and placements of the SRAF and the main pattern are based on iteration processes.

With respect to placement of SRAFs, several possible SRAF placement solutions may be possible. For example, one possible SRAF placement technique is a rule based SRAF placement method. In this method, numerous test patterns and corresponding wafer images are obtained to populate empirical data and the empirical data is studied and analyzed to establish the rules. SRAFs are then placed on a mask based on such rules. Because SRAFs are placed based on a rule table, the turn-around-time is short. However, because the test patterns may not be representative of the actual patterns, the rule based SRAF placement techniques may suffer from unsatisfactory accuracy.

Another possible SRAF placement technique is inference mapping lithography (IML). A real-world exposure tool uses a partially coherent radiation source and the partial coherence may be decomposed into a sum of coherent systems (SOCS) by performing decomposition on a transmission cross coefficient (TCC). In terms of optical physics, the TCC represents autocorrelation of the radiation source of the exposure tool with the projection pupil of the exposure tool. Therefore, the TCC is a mathematical representation of the imaging capability of the exposure tool, which includes an ensemble of various exposure conditions of the exposure tool. The TCC may be decomposed into a set of eigenfunctions (Φ) and a set of eigenvalues (k). ML only considers the first order eigenfunction of the TCC to determine SRAF placement. Because only the first order eigenfunction is included in IML, the effect of exposure conditions of the exposure tool may not be sufficiently factored and accuracy may be less than satisfactory.

Another possible SRAF placement technique is called inverse lithography technology (ILT). In this technique, instead of calculating the aerial image based on a given mask design, it calculates a mask design necessary to generate a target aerial image. Although ILT may have superior accuracy, its turn-around-time may be unduly long and intractable. In some instances, ILT may require more than 300 times of the amount of time needed to conclude a rule based SRAF placement process. That is why ILT is currently mostly used to perform spot repairs of mask.

The present disclosure is directed to a method of, generating the SRAF and the main pattern based on the target pattern. Thus, the SRAF is not generated based on the main pattern, but both the SRAF and the main pattern are generated together based on the target pattern. This method overcomes inaccuracy of the generating the SRAF by having the main pattern, due to the dependency of the main pattern to the SRAF. In addition, the disclosed method includes placing the SRAF on the photolithography mask based on an estimation of the light transmission, while the photolithography mask is blank. Hence, the position of the SRAF as well as the main pattern are estimated simultaneously. In various embodiments of the present disclosure, the generation and placements of the SRAF and the main pattern are based on iteration processes.

IC manufacturing includes multiple entities, such as a design house, a mask house, and an IC manufacturer (e.g., a fab). These entities interact with one another in the design, development, and manufacturing cycles and/or services related to manufacturing an integrated circuit (IC) device. These entities are connected by a communications network, which may be a single network or a variety of different networks, such as an intranet and the Internet, and may include wired and/or wireless communication channels. Each entity may interact with other entities and may provide services to and/or receive services from the other entities. One or more of the design house, mask house, and IC manufacturer may have a common owner, and may even coexist in a common facility and use common resources. In various embodiments, the design house, which may include one or more design teams, generates an IC design layout. The IC design layout may include various geometrical patterns designed for the fabrication of the IC device. By way of example, the geometrical patterns may correspond to patterns of metal, oxide, or semiconductor layers that make up the various components of the IC device to be fabricated. The various layers collectively form various features of the IC device. For example, various portions of the IC design layout may include features such as an active region, a gate electrode, source and drain regions, metal lines or vias of a metal interconnect, openings for bond pads, as well as other features known in the art which are to be formed within a semiconductor substrate (e.g., such as a silicon wafer) and various material layers disposed on the semiconductor substrate. In various examples, the design house implements a design procedure to form the IC design layout. The design procedure may include a logic design, a physical design, and/or a place and route. The IC design layout may be presented in one or more data files having information related to the geometrical patterns, which are to be used for fabrication of the IC device. In some examples, the IC design layout may be expressed in a graphic design system (GDS)-II file format or design framework (DF)-II file format.

In some instances, the design house may transmit the IC design layout to the mask house, for example, via the network connection described above. The mask house may then use the IC design layout to generate a mask design, such as the first mask design, modify the mask design to form a modified mask design, and manufacture one or more masks to be used for fabrication of the various layers of the IC device according to the modified mask design. In various examples, the mask house performs mask data preparation, where the IC design layout is translated into a form that can be physically written by a mask writer, and mask fabrication, where the design layout prepared by the mask data preparation is modified to generate a modified mask design and is then fabricated. In some embodiments of the present disclosure, some of the operations described above are not performed by the mask house, but the IC manufacturer, especially when information of the exposure tool is used.

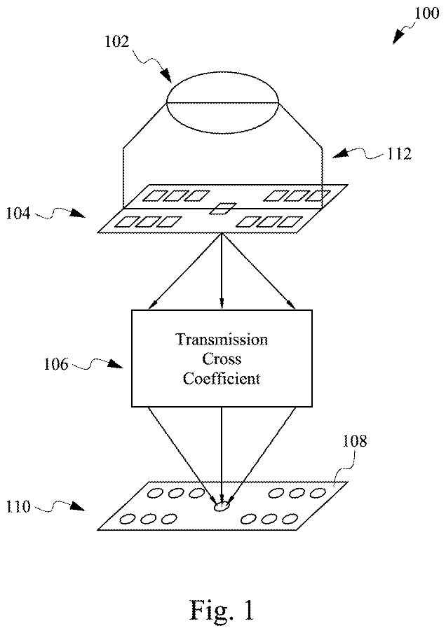

FIG. 1 is a photolithography system 100 including an exposure tool (e.g., an optical stepper and an optical scanner) having a light source (radiation source) 102, a photolithography mask (reticle) 104, a pupil plane 106, and an aerial image 108 on a substrate (e.g., a silicon wafer) 110. The light source 102 may illuminate a light beam 112 expressed as a function S (S(f, g)), where f and g are coordinates on a plane at the light source 102. The photolithography mask 104 may be expressed as a function a(x, y) (or m(x, y)), where x and y are coordinates on a plane at the photolithography mask 104. Light (radiation) diffracted by features on the photolithography mask 104 may be expressed as a Fourier Transform of the mask function: â(f, g)=FT[a(x, y)]. At the pupil plane 106, a pupil function is represented as a function of P, P(f, g). A complex conjugate of the pupil function is given by a function of P*(f, g). The transmission cross coefficient TCC may be obtained by:

$$TCC ( {f}_{1} , {g}_{1} , {f}_{2} , {g}_{2} ) = \int \int S ( f , g ) P ( f + {f}_{1} , g + {g}_{1} ) {P}^{*} ( f + {f}_{2} , g + {g}_{2} ) dfdg .$$

The aerial image I (x, y) may be given by:

$$I ( x , y ) = \int \int \int TCC ( {f}_{1} , {g}_{1} , {f}_{2} , {g}_{2} ) \hat{a} ( {f}_{1} , {g}_{1} ) {{\hat{a}}^{*} ( {f}_{2} , {g}_{2} )}^{- i 2 π [ ( {f}_{1} + {f}_{2} ) x + ( {g}_{1} - {g}_{2} ) y ]} {df}_{1} {dg}_{1} {df}_{2} {dg}_{2} .$$

In some embodiments, the radiation of the light source 102 may be polarized and the polarization may be changed by the photolithography mask 104. For example, the radiation of the light source 102 incident on the photolithography mask 104 may be polarized in the X direction and the light diffracted by the photolithography mask 104 may be polarized in the Y direction at the pupil plane 106. With respect to such a near field incoming and outgoing radiation pair, a function of the photolithography mask 104 includes an X-Y component (a^{ixy}(x, y)) and the X-Y component represents a simulated interaction between the X-polarized radiation on the photolithography mask 104 and the Y-polarization radiation on the pupil plane 106. Similarly, with respect to the X-polarized incident radiation and X-polarized outgoing radiation, the function of the photolithography mask 104 includes an X-X component (a^{ixx}(x, y)); with respect to the Y-polarized incident radiation and X-polarized outgoing radiation, the function of the photolithography mask 104 includes a Y-X component (a^{iyx}(x, y)); and with respect to the Y-polarized incident radiation and Y-polarized outgoing radiation, the function of the photolithography mask 104 includes a Y-Y component (a^{iyy}(x, y)). In cases where the design of the photolithography mask 104 is assumed to be implemented as an ideal mask, the X-X, X-Y, Y-X, and Y-Y components are identical to one another. In cases where the design of the photolithography mask 104 is assumed to be implemented as a real-world mask with a three-dimensional (3D) effect of the photolithography mask 104, the X-X, X-Y, Y-X, and Y-Y components are not identical and should be considered separately.

Although FIG. 1 shows a transmission type of the photolithography mask 104 used in, for example, a KrF or an ArF excimer laser lithography system (optical scanner/stepper), an extreme ultraviolet (EUV) lithography system using a reflective photolithography mask can also be expressed by the same equations.

In the photolithography system 100, various parameters including, but not limited to, a wavelength of the light source 102, a numerical aperture (NA) of the optical system coupled to the light source 102 (e.g., lenses), information regarding illumination (e.g., illumination shapes such as annular illumination, multipole illumination, etc.), information regarding lens aberration, information regarding polarization of the light, information regarding a film stacking structure on which a photoresist layer is formed, information regarding a mask three-dimensional (3D) effect, and information regarding the photoresist layer are specified.

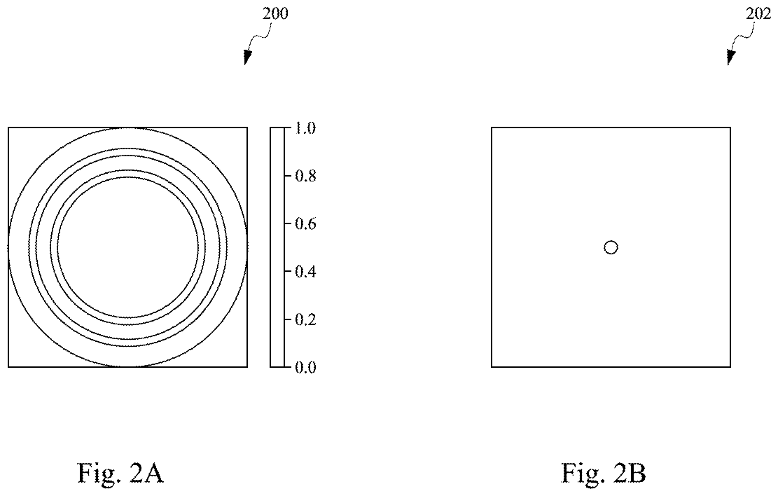

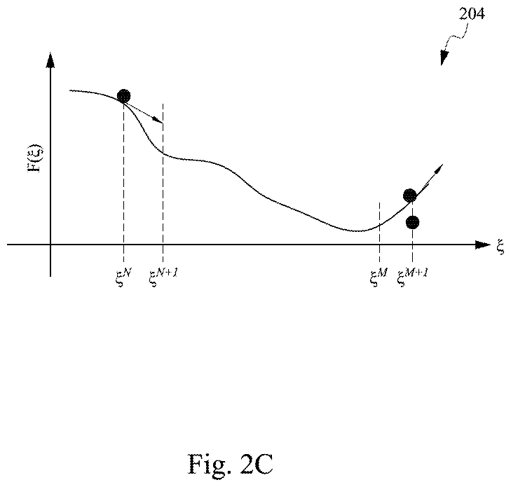

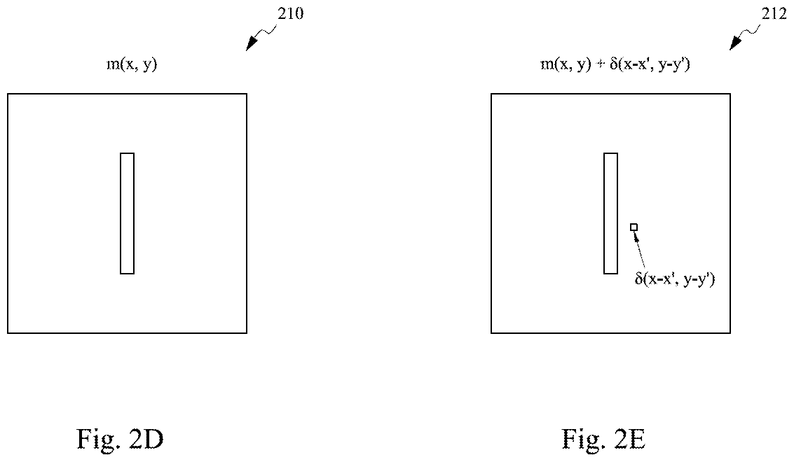

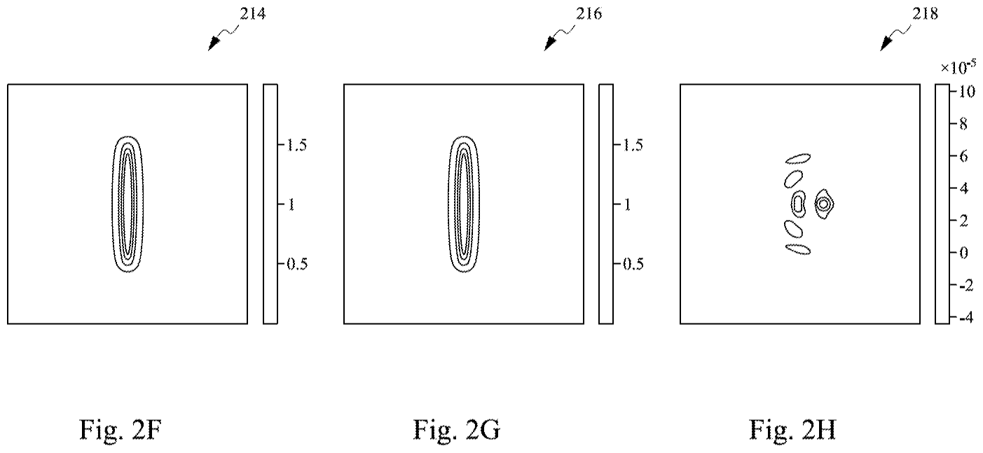

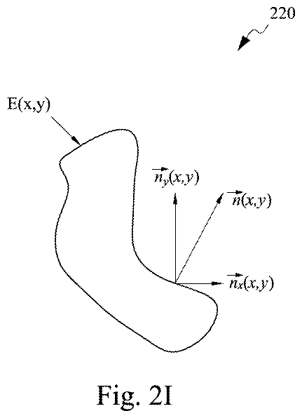

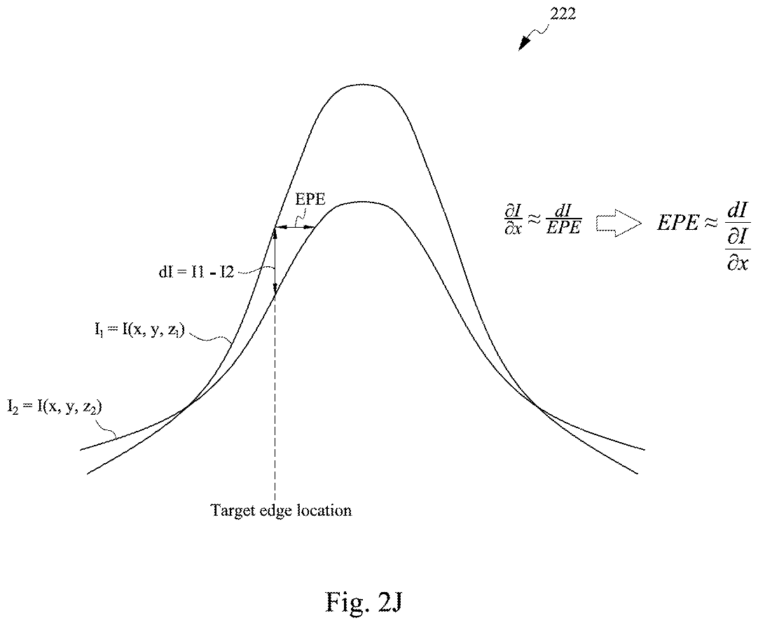

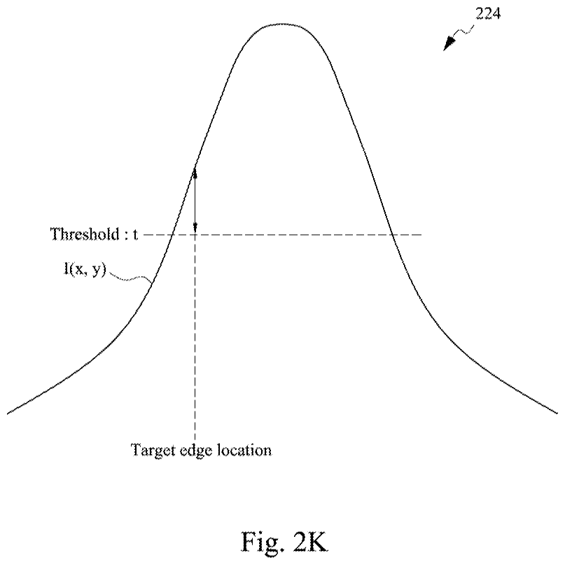

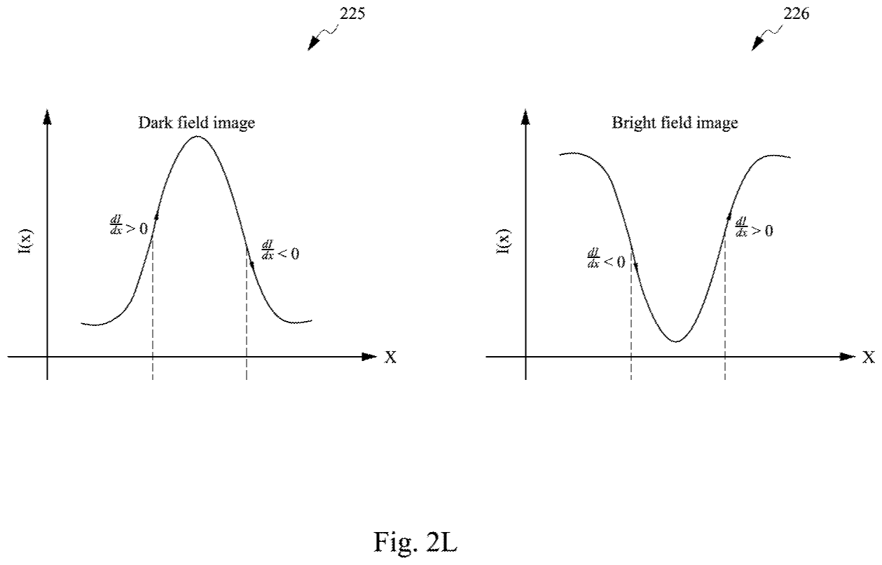

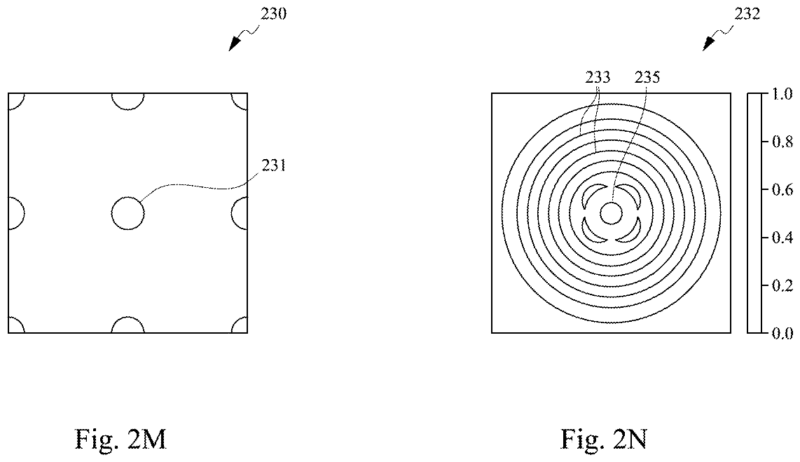

FIG. 2A illustrates an annular illumination model 200 associated with calculating an SRAF seed map for a given photolithography exposure profile, in accordance with some embodiments. In example, the central photolithography wavelength is 193 nm. In one example, the numerical aperture has a value of 1.35. A cost function is also associated with the model. The X axis of the model 200 corresponds to a dimension f. The y-axis of the model 200 corresponds to a dimension g. On the right side of the model 200, is a legend illustrating intensity from a minimum of 0 to a maximum of 1.

FIG. 2B is a target pattern 202 associated with the model 200 of FIG. 2A, in accordance with some embodiments. In this example, the target pattern corresponds to a circular contact hole to be formed on a wafer. As an example, the circular contact hole may correspond to a location in which a conductive via will be formed. In one example, the diameter of the circular contact hole is 50 nm, though other dimensions can be utilized without departing from the scope of the present disclosure. In accordance with principles of the present disclosure, no main pattern is initially utilized for generation of the SRAF for the mask.

FIG. 2C illustrates a graph 204 of a cost F(ξ) associated with the model 200 of FIG. 2A, in accordance with some embodiments. In an optimization problem, it is beneficial to define a cost function F(ξ). The function F(x) may be maximized or minimized with respect to x. The function F(ξ) may be called an objective function in general. However, in the context of generation of a photolithography pattern, the function F(ξ) will be referred to as a cost function hereafter.

In order to find the minimum of F(ξ), it is beneficial to find the gradient F′(ξ) of the cost function F(ξ). The gradient corresponds to the slope or derivative of the function F(ξ). The graph 204 illustrates particular function values ξ^{N}, ξ^{N+1}, ξ^{M}, and ξ^{M+1} in order to illustrate concepts associated with the gradient. As can be seen, the gradient that ξ^{N} is negative (i.e., the downward slope). The point ξ^{N+1} is closer to a minimum than ξ^{N}. The value at ξ^{N+1} can be given as the value at ξ^{N} minus the slope at ξ^{N} multiplied by constant (e.g., alpha, as described below). The gradient at point ξ^{M} is greater than zero (i.e., an upward slope). ξ^{M+1} is closer to maximum than ξ^{M}. For a given point k, updating ξ^{k} as ξ^{k+1} equals ξ^{k} minus the gradient of ξ^{k} multiplied by the cost of α (alpha) is a good way to find a minimum or maximum of F(ξ).

FIGS. 2D-2H are illustrations of masks and optical profiles associated with exposure via masks, in accordance with some embodiments. FIG. 2D is a simple illustration of a mask pattern 210, in accordance with some embodiments. FIG. 2E is a simple illustration of a mask pattern 212 with a slight variation with respect to the pattern of FIG. 2D. In particular, a small pinhole is implemented in the mask pattern of FIG. 2E. The small mask pinhole can be expressed by the Dirac delta function δ(x-x′, y-y′). In one embodiment, the gradient shows if an image slope is improved at the target edge with a pinhole placed at x′, y′. If the gradient is positive, then the image slope is improved.

FIG. 2F corresponds to an image 214 associated with the mask pattern 210, in accordance with some embodiments. FIG. 2G corresponds to an image 216 associated with the mask pattern 212 of FIG. 2E. FIG. 2H corresponds to the difference 218 between the images 214 and 216 of FIGS. 2F and 2G, in accordance with some embodiments. Accordingly, FIG. 2H corresponds to the intensity gradient with respect to the mask patterns 212 and 214, in accordance with some embodiments.

In some embodiments, if we change the position of the pinhole (x′, y′), then the intensity gradient changes as well. Accordingly, the intensity gradient g can be expressed as g(x, y, x′,y′). If the focus is placed on the intensity change at a given point (x0, y0) within the pattern (i.e., within the rectangular pattern), then the intensity gradient can be expressed as g(x0, y0, x′, y′). As (x0, y0) is held constant, the gradient is a function g(x′,y′). Accordingly, the gradient g(x′,y′) shows out the intensity at (x0, y0) changes with a pinhole placed at (x′, y′).

Now consider three points (x0, y0), (x1,y1), and (x2, y2) within the rectangular pattern of FIG. 2D/2E. We can focus on the intensity change at each of these three points. We can then define the 2D gradient function g(x′, y′) as the sum of the gradients g(x0, y0, x′, y′), g(x1, y1, x′, y′), and g(x2, y2, x′, y′). The 2D gradient function g(x′,y′) is a sum of the intensity change at the three points with a pinhole placed at (x′,y′).

Now assume that we would like to know the intensity change inside a polygon (such as the rectangle pattern of FIGS. 2D and 2E, or polygon of another shape having X and Y coordinates. The 2D gradient function g(x′, y′) can be given as:

$$g ( {x}^{′} , {y}^{′} ) = {\int \int }_{\begin{matrix}x . y . inside \\ polygon\end{matrix}} g ( x , y , {x}^{′} , {y}^{′} ) dxdy$$

for all points (x, y) within the polygon. Accordingly, g(x′, y′) indicates how the intensity inside the polygon changes with a pinhole placed at (x′, y′). More generally, the gradient function can be written with a function that represents a target w(x, y):

$$g ( {x}^{′} , {y}^{′} ) = \int \int g ( x , y , {x}^{′} , {y}^{′} ) w ( x , y ) dxdy$$

In this way, we can define a 2D gradient function g(x′, y′) with the help of a target function w(x, y).

In some embodiments, the cost function can be an ILS cost function. FIG. 2I illustrates an example target polygon 220 having an edge function E(x, y). The ILS cost function CILS can be given with the following relationship:

$${C}_{ILS} ( x , y , {x}^{′} , {y}^{′} ) = ( \frac{\partial I ( x , y , {x}^{′} , {y}^{′} )}{\partial x} {n}_{x} + \frac{\partial I ( x , y , {x}^{′} , {y}^{′} )}{\partial y} {n}_{y} ) - ( \frac{\partial I ( x , y )}{\partial x} {n}_{x} + \frac{\partial I ( x , y )}{\partial y} {n}_{y} )$$

The gradient g_{ILS}(x′, y′) associated with this cost function for this polygon can be given by the following relationship:
This gradient shows if the image slope is improved the target edge E(x,y) with a pinhole placed at (x′, y′). If the gradient is positive, then the image slope has improved. By testing pinhole placement at various locations and calculating the gradient for each location with respect to the previous location in iterations, an optimum pinhole placement can be found. This process can be utilized to

$${g}_{ILS} ( {x}^{′} , {y}^{′} ) = \int \int {C}_{ILS} ( x , y , {x}^{′} , {y}^{′} ) E ( x , y ) dxdy$$

identify desired placement of a SRAF pattern.

In some embodiments, an EPE (edge placement error) cost function can be utilized. FIG. 2J is a graph 222 illustrating concepts associated with utilization of an EPE cost function, in accordance with some embodiments. With reference to FIG. 2J, an EPE cost function C_{EPE} the given by the following formula:

$${C}_{EPE} ( x , y , {x}^{′} , {y}^{′} ) = \frac{{[ I ( x , y , {x}^{′} , {y}^{′} , {z}_{2} ) - I ( x , y , {x}^{′} , {y}^{′} , {z}_{1} ) ]}^{2}}{\sqrt{{( \frac{\partial I}{\partial x} )}^{2} + {( \frac{\partial I}{\partial y} )}^{2}}} - \frac{{[ I ( x , y , {z}_{2} ) - I ( x , y , {z}_{1} ) ]}^{2}}{\sqrt{{( \frac{\partial I}{\partial x} )}^{2} + {( \frac{\partial I}{\partial y} )}^{2}}}$$

The gradient g_{EPE}(X′,y′) can be given by the following formula:

$${g}_{EPE} ( {x}^{′} , {y}^{′} ) = - \int \int {C}_{EPE} ( x , y , {x}^{′} , {y}^{′} ) E ( x , y ) dxdy$$

The minus sign is put in the gradient function such that the positive gradient reduces EPE.

In some embodiments, and on target cost function C_{OT} can be utilized. FIG. 2K illustrates principles associated with an on-target cost function, in accordance with some embodiments. With reference to FIG. 2K, the on-target cost function can be given by the following relationship:

$${C}_{OT} ( x , y , {x}^{′} , {y}^{′} ) = {[ I ( x , y , {x}^{′} , {y}^{′} ) - t ]}^{2} - {[ I ( x , y ) - t ]}^{2}$$

The gradient g_{OT}(x′y′) of the on-target cost function can be given by the following formula:

$${g}_{OT} ( {x}^{′} , {y}^{′} ) = - \int \int {C}_{OT} ( x , y , {x}^{′} , {y}^{′} ) E ( x , y ) dxdy$$

The minus sign is put in the gradient such that the positive gradient corresponds to a good result.

In some embodiments, a depth of focus (DOF) cost function can be utilized. The DOF cost function can utilize aspects of FIG. 2J. The DOF cost function C_{DOF} can be given by the following relationship:

$${C}_{DOF} ( x , y , {x}^{′} , {y}^{′} ) = {[ I ( x , y , {x}^{′} , {y}^{′} , {z}_{2} ) - I ( x , y , {x}^{′} , {y}^{′} , {z}_{1} ) ]}^{2} - {[ I ( x , y , {z}_{2} ) - I ( x , y , {z}_{1} ) ]}^{2}$$

The gradient g_{DOF} of the DOF cost function can be given by the following relationship:

$${g}_{DOF} ( {x}^{′} , {y}^{′} ) = - \int \int {C}_{DOF} ( x , y , {x}^{′} , {y}^{′} ) E ( x , y ) dxdy$$

The minus sign is put in the gradient such that the positive gradient shows a better DOF.

In some embodiments, principles of the present disclosure utilize the cost function in generating a SRAF pattern. A mask generation process obtains a minimum or maximum of the cost function by calculating the gradient of the cost function using one or more of the methods described above. In some embodiments, the cost function is a function of a mask m(x, y). Therefore m(x,y) is treated as a variable. The mask can also be treated as pixelated. The mask can be updated in the following manner:

$${m}^{k + 1} ( x , y ) = {m}^{k} ( x , y ) - α g ( x , y )$$

in which α is constant to determine the speed of convergence. Accordingly, the mask may be optimized in iterations. The diffraction of the mask can be calculated as described previously. One or more of the cost functions described above can be utilized to determine the gradient. If more cost functions than one are considered, each cost function is weighted to obtain the final gradient. The layout of the mask is adjusted in iterations for which the gradient is calculated until a desired layout is found. FIG. 2L illustrates graphs 225 and 216 for a dark-field image and a brightfield image, and corresponding slopes for various portions of the graphs.

Principles described in relation to FIGS. 2A-2L can be utilized to generate a layout of a mask based on a target pattern. The layout of the mask includes SRAF patterns and a main pattern. As will be set forth in more detail below, the mask generation process generates a SRAF pattern without a main pattern already present. This can greatly enhance the efficiency and effectiveness of mask generation.

FIG. 2M is an illustration of a target 230, in accordance with some embodiments. The target pattern 231 corresponds to a planned layout for features to be formed on a wafer. In the example of FIG. 2M, the layout includes a contact hole 231. In practice, a target layout may have different features and combinations of features without departing from the scope of the present disclosure.

FIG. 2N is an illustration of a mask layout 232 which consists of variable transmittance, according to one embodiment. Utilizing principles of the present disclosure, the mask 232 has been generated based on the target 230. In particular, without a main pattern for the mask 232, it is generated. The mask 232 can be generated iteratively and by calculating the gradient using a cost function, as described previously.

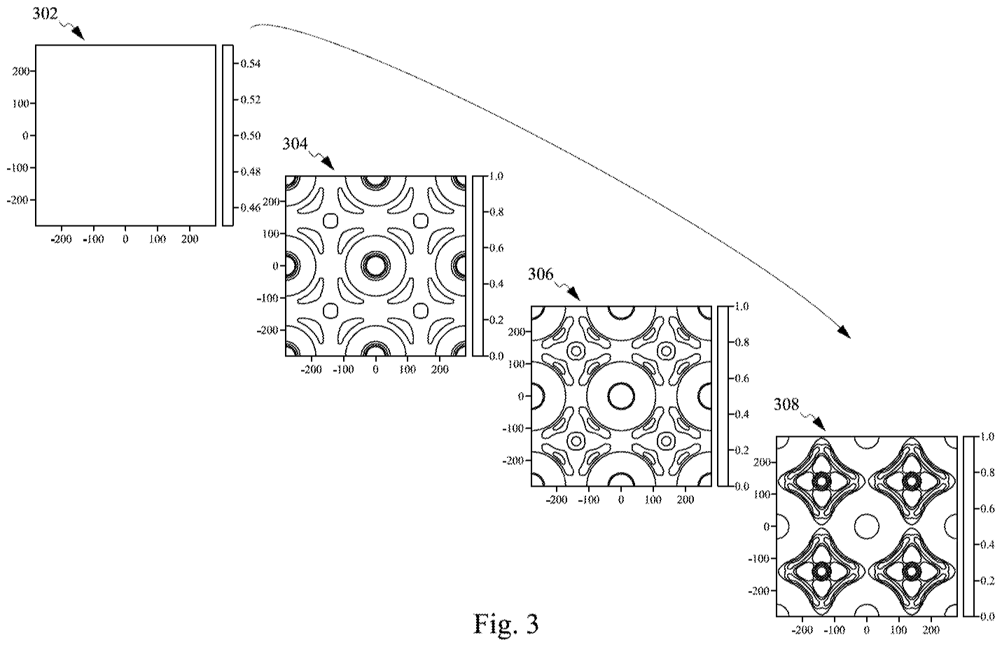

FIG. 3 illustrates a process 300 for generating a mask layout, in accordance with some embodiments. The process 300 can utilize components, systems, and processes described in relation to FIGS. 1-2N. At 302, a blank mask layout is set as an initial mask. A target 230 is also provided. The target corresponds to a planned layout for features to be formed on a wafer. In the example of the process 300, the target may correspond to a layout for one or more circular contact holes. Notably, there is no main pattern present on the mask at 302. Through iteration, the mask pattern develops from 302 to 304, 306, and 308 according to a given cost function.

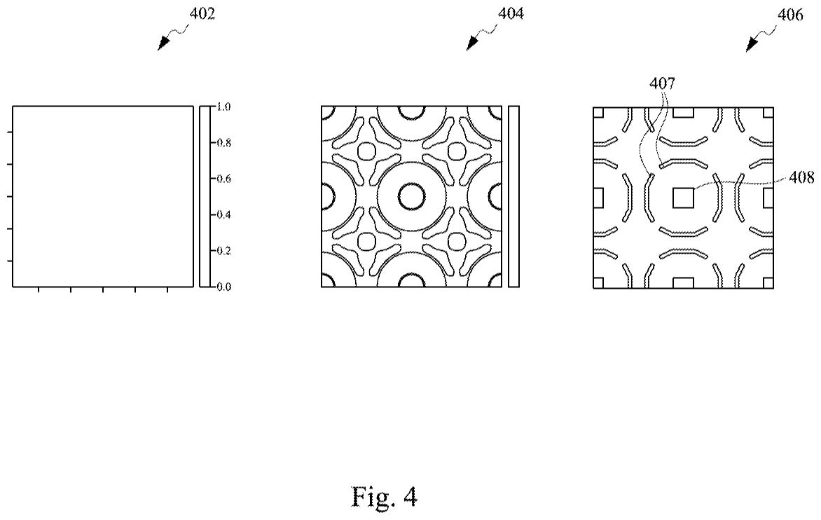

FIG. 4 illustrates a process 400 for generating a mask layout, in accordance with some embodiments. The process 400 can utilize components, systems, and processes described in relation to FIGS. 1-3. At 402, and initial mask layout is blank. There is no main pattern on the initial mask layout. At 404, a mask pattern is generated based on a target pattern and utilizing a cost function, as described previously. Through a plurality of iterations at 404, a SRAF seed map will be obtained which shows where to place SRAF. At 406, a SRAF pattern 407 and main pattern 408 is placed on the mask pattern based on the SRAF seed map. In the example of FIG. 4, the main pattern is a square, though other shapes of the main pattern can be utilized without departing from the scope of the present disclosure. OPC can then be applied to the main pattern to generate a final mask layout. When the final mask layout has been generated, the actual physical photolithography mask can be fabricated using the final mask pattern including the SRAF pattern 407 and the main pattern 408.

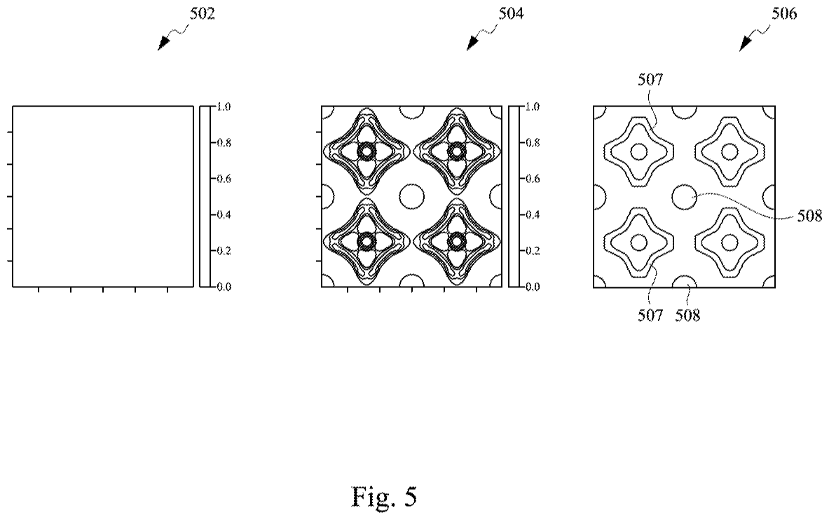

FIG. 5 illustrates a process 500 for generating a mask layout, in accordance with some embodiments. The process 500 can utilize components, systems, and processes described in relation to FIGS. 1-4. At 502, and initial mask layout is blank. There is no main pattern on the initial mask layout. At 504, a mask pattern is generated based on a target pattern and utilizing a cost function, as described previously. Through a plurality of iterations at 504, a final mask pattern can be generated when the cost is sufficiently optimized (e.g., max or min). In one embodiment, between 250 and 350 iterations may be performed at step 504. Higher values on scale of the right of 504 correspond to the mask pattern layout or mask pattern polygon. Accordingly, the circular features correspond to the mask pattern layout or mask pattern polygons, according to one embodiment. At 506, and optimize pattern has been laid out. The optimize pattern may include a SRAF pattern 507 and the main pattern 508. OPC can then be applied to the main pattern for fine-tuning to generate a final mask layout. When the final mask layout has been generated, the actual physical photolithography mask can be fabricated using the final mask pattern including the SRAF pattern 507 and the main pattern 508.

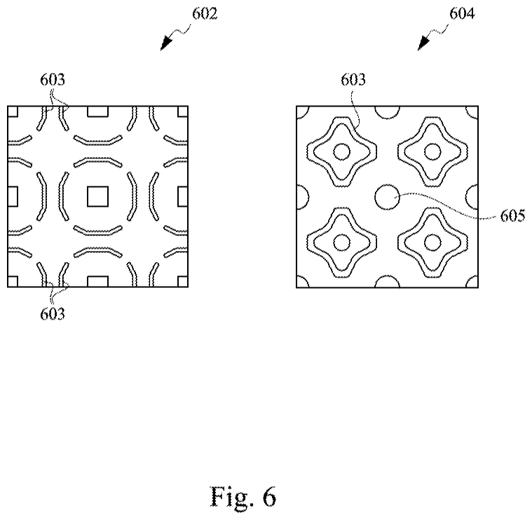

FIG. 6 includes a mask pattern layout 602 and another mask layout 604, according to one embodiment. The mask pattern layout 602 can be generated from a blank mask layout, as described previously. An SRAF pattern 603 may be formed based on a target layout. In the mask layout 604, the SRAF pattern 603 and a main pattern 605 have been formed. In one embodiment, the target pattern corresponds to a pattern of squares with 50 nm side length.

FIG. 7 illustrates process windows to evaluate robustness of the lithography process, in accordance with some embodiments.

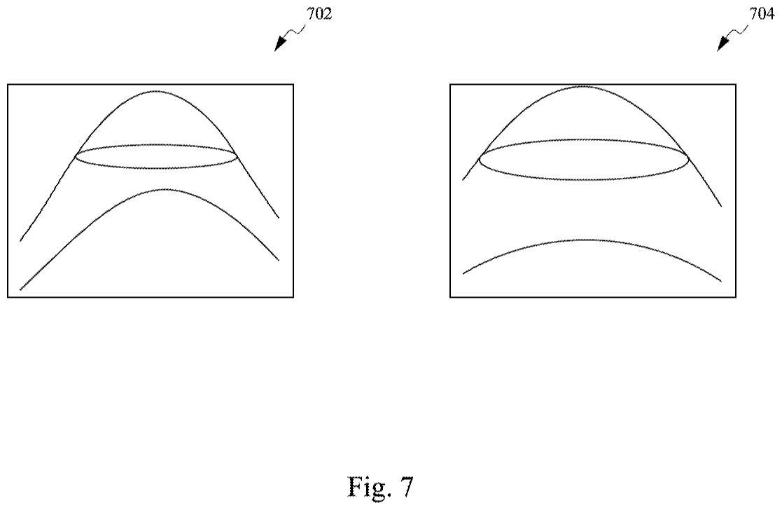

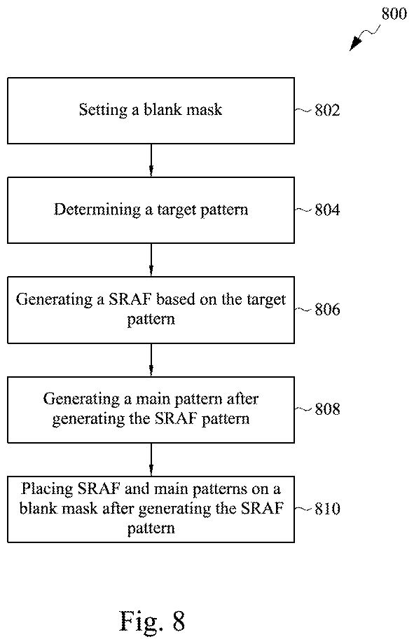

FIG. 8 is a flow diagram of a method 800 for preparing a mask for use in a photolithographic patterning of a layer on a substrate, in accordance with some embodiments. The method 800 can utilize processes, components, and systems described in relation to FIGS. 1-7 as well as subsequent figures. At 802, the method 800 includes setting a blank mask. One example of a blank mask is the blank mask at step 402 of FIG. 4. At 804, the method 800 includes determining a target pattern. One example of a target pattern is the pattern of square shapes in the layout 602 of FIG. 6. At 806, the method 800 includes generating a SRAF and main patterns based on the target pattern. One example of a SRAF pattern is the SRAF pattern 603 of FIG. 6. One example of a main pattern is the main pattern 605 of FIG. 6. At 808, the method 800 includes optimizing SRAF and main patterns by iteration process. At 810, the method 800 includes placing the SRAF pattern and the main pattern on the blank mask after generating the SRAF pattern.

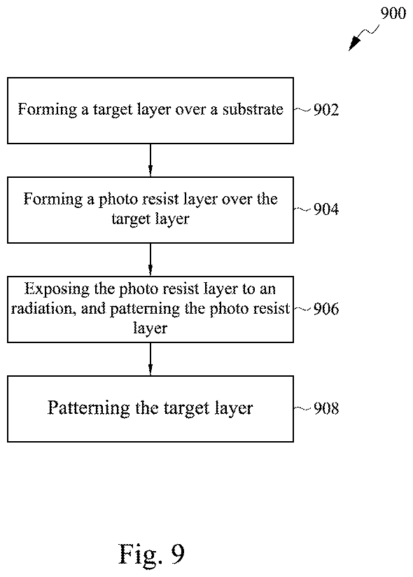

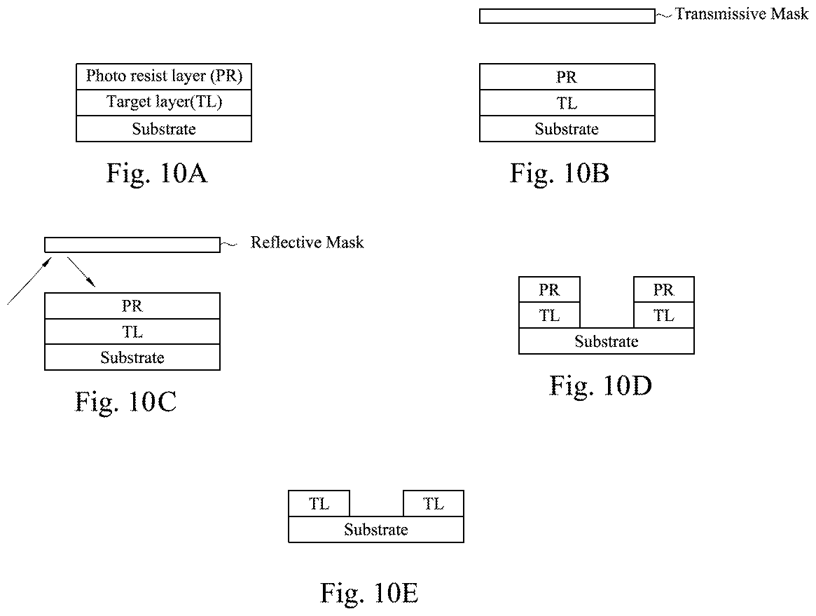

FIG. 9 is a flow diagram of a method 900, in accordance with some embodiments. The method 900 can utilize systems, components, and processes described in relation to FIGS. 1-8 as well as subsequent figures. At 902, the method 900 includes forming a target layer over a substrate. The target layer corresponds to a layer that will be patterned in a photolithography process. Accordingly, the target layer may correspond to the layer on a wafer intended to be patterned in accordance with a photolithography mask. The target layer may be a layer in which conductive vias, metal lines, semiconductor fins, dielectric structures, or other types of features will be formed. The target layer may also be a hard mask layer. Accordingly, the target layer may be a layer of semiconductor material, dielectric material, conductive material, or other types of materials. At 904, the method 900 includes forming a photoresist layer over the target layer. At 906, the method 900 includes exposing the photoresist layer to EUV radiation in patterning the photoresist layer. The photoresist layer can be exposed to EUV radiation via a mask that is generated using processes and systems described herein. In particular, the mask includes a SRAF pattern and a main pattern generated using one or more the processes described herein. At 908, the method 900 includes patterning the target layer. One example of the substrate, target layer, and photoresist layer described in FIG. 9 is shown in relation to FIGS. 10A-10E. FIGS. 10A-10E are described below.

FIGS. 10A-10E show a process flow of a method of making a semiconductor device, in accordance with some embodiments. In particular, each of FIGS. 10A-10E are cross-sectional views of a wafer on which layers are formed and patterned using a photolithography mask generated in accordance with principles of the present disclosure. A semiconductor substrate or other suitable substrate to be patterned to form an integrated circuit thereon is provided. In some embodiments, the semiconductor substrate includes silicon. Alternatively, or additionally, the semiconductor substrate includes germanium, silicon germanium or other suitable semiconductor material, such as a Group III-V semiconductor material.

In FIG. 10A, a target layer to be patterned is formed over the semiconductor substrate. The target layer corresponds to a layer that will be patterned in a photolithography process. Accordingly, the target layer may correspond to the layer on a wafer intended to be patterned in accordance with a photolithography mask. The target layer may be a layer in which conductive vias, metal lines, semiconductor fins, dielectric structures, or other types of features will be formed. The target layer may also be a hard mask layer. In certain embodiments, the target layer is a semiconductor substrate. In some embodiments, the target layer includes a conductive layer, such as a metallic layer or a polysilicon layer; a dielectric layer, such as silicon oxide, silicon nitride, SiON, SiOC, SiOCN, SiCN, hafnium oxide, or aluminum oxide; or a semiconductor layer, such as an epitaxially formed semiconductor layer. In some embodiments, the target layer is formed over an underlying structure, such as isolation structures, transistors or wirings. A photo resist layer is formed over the target layer. The photo resist layer is sensitive to the radiation from the exposing source during a subsequent photolithography exposing process. The photo resist layer may be formed over the target layer by spin-on coating or other suitable techniques. The coated photo resist layer may be further baked to drive out solvent in the photo resist layer.

In FIG. 10B, the photoresist layer is patterned using an optical lithography tool. In some embodiments, the optical lithography tool is an ArF or a KrF excimer laser scanner using a transmissive mask as shown in FIG. 10B. The transmissive mask includes SRAF patterns as explained above. More particularly, the transmissive mask has been formed by generating a SRAF pattern from a blank mask layout as described previously. In other embodiments, the optical lithography tool is an EUV scanner using a reflective mask including SRAF patterns, as shown in FIG. 10C. During the exposing process, the integrated circuit (IC) design pattern defined on the mask is imaged to the photoresist layer to form a latent pattern thereon, without printing the SRAF patterns. The patterning of the photoresist layer further includes developing the exposed photoresist layer to form a patterned photoresist layer having one or more openings. In one embodiment where the photoresist layer is a positive tone photoresist layer, the exposed portions of the photoresist layer are removed during the developing process. The patterning of the photoresist layer may further include other process steps, such as various baking steps at different stages. For example, a post-exposure-baking (PEB) process may be implemented after the photolithography exposing process and before the developing process.

In FIG. 10D, patterning the target layer includes applying an etching process to the target layer using the patterned photoresist layer as an etch mask. The portions of the target layer exposed within the openings of the patterned photoresist layer are etched while the remaining portions are protected from etching. Further, the patterned photoresist layer may be removed by wet stripping or plasma ashing, as shown in FIG. 10E.

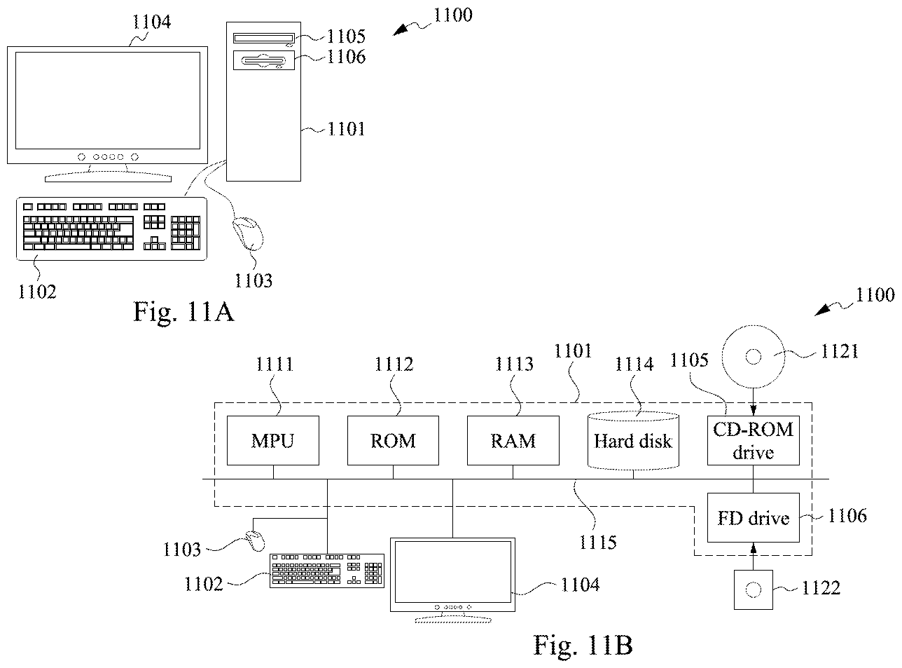

FIGS. 11A and 11B illustrate an apparatus for manufacturing a lithographic mask for a semiconductor circuit in accordance with some embodiments of the disclosure. In some embodiments, the apparatus is an optical simulator.

FIG. 11A is a schematic view of a computer system that executes the process for manufacturing the lithographic mask according to one or more embodiments as described above. All of or a part of the processes, method and/or operations of the foregoing embodiments can be realized using computer hardware and computer programs executed thereon. The operations include OPC correction, TCC kernel calculation, SRAF seed map calculation, SRAF placement, etc., as set forth above. In FIG. 11A, a computer system 1100 is provided with a computer 1101 including an optical disk read only memory (e.g., CD-ROM or DVD-ROM) drive 1105 and a magnetic disk drive 1106, a keyboard 1102, a mouse 1103, and a monitor 1104.

FIG. 11B is a diagram showing an internal configuration of the computer system 1100. The computer 1101 is provided with, in addition to the optical disk drive 1105 and the magnetic disk drive 1106, one or more processors 1111, such as a micro processing unit (MPU), a ROM 1112 in which a program, such as a boot up program is stored, a random access memory (RAM) 1113 that is connected to the MPU 1111 and in which a command of an application program is temporarily stored and a temporary storage area is provided, a hard disk 1114 in which an application program, a system program, and data are stored, and a bus 1115 that connects the MPU 1111, the ROM 1112, and the like. Note that the computer 1101 may include a network card (not shown) for providing a connection to a LAN.

The program for causing the computer system 1100 to execute the process for calculating the SRAF seed map and placing the SRAF patterns in the foregoing embodiments may be stored in an optical disk 1121 or a magnetic disk 1122, which are inserted into the optical disk drive 1105 or the magnetic disk drive 1106, and transmitted to the hard disk 1114. Alternatively, the program may be transmitted via a network (not shown) to the computer 1101 and stored in the hard disk 1114. At the time of execution, the program is loaded into the RAM 1113. The program may be loaded from the optical disk 1121 or the magnetic disk 1122, or directly from a network. The program does not necessarily have to include, for example, an operating system (OS) or a third-party program to cause the computer 1101 to execute the process for manufacturing the lithographic mask of a semiconductor device in the foregoing embodiments. The program may only include a command portion to call an appropriate function (module) in a controlled mode and obtain desired results.

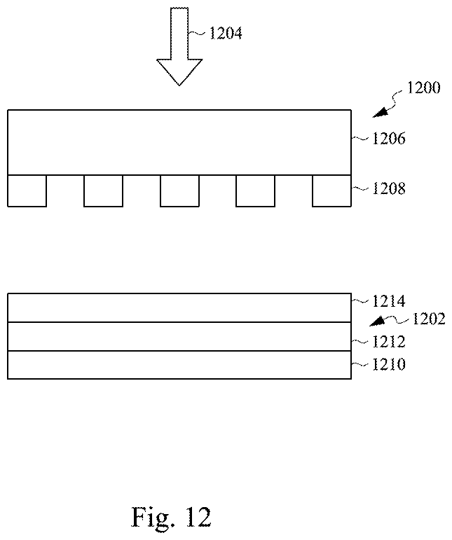

FIG. 12 is an illustration of a photolithography mask 1200 and a semiconductor wafer 1202, in accordance with some embodiments. The photolithography mask 1200 includes a substrate or body 1206 and a patterned material 1208. The patterned material 1208 is coupled to the substrate 1206. The pattern of the patterned material 1208 corresponds to the SRAF pattern and the main pattern of the photolithography mask 1200. In one embodiment, the substrate 1206 includes silicon oxide. In one embodiment, the patterned material includes one or more of chromium, molybdenum, silicon, or other materials. In practice, the photolithography mask 1200 can include many other materials and structures without departing from the scope of the present disclosure. The pattern of the photolithography mask 1200 is generated from a blank mask pattern based on a target layout as described previously.

The semiconductor wafer 1202 includes a substrate 1210, a patterned layer 1212, and a photo resist layer 1214. In a photolithography process, photolithography light 1204 is transmitted through the mask 1200 toward the semiconductor wafer 1202. After the light is transmitted through the photolithography mask 1200, the light 1204 has a pattern corresponding to the pattern of the photolithography mask 1200. The light interacts with the photoresist layer 1214. After development, the photoresist layer 1214 carries a pattern in accordance with the pattern of the photolithography mask. An etching process can then be performed to impart the pattern into the pattern layer 1212 of the semiconductor wafer 1202. Various other processes can be utilized without departing from the scope of the present disclosure.

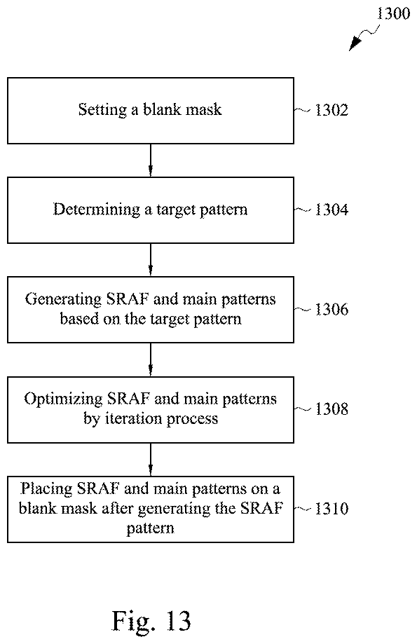

FIG. 13 is a flow diagram of a method 1300 for preparing a mask for use in a photolithographic patterning of a layer on a substrate, in accordance with some embodiments. The method 1300 can utilize processes, components, and systems described in relation to FIGS. 1-12. At 1302, the method 1300 includes setting a blank mask. One example of a blank mask is the blank mask at step 402 of FIG. 4. At 1304, the method 1300 includes determining a target pattern. One example of a target pattern is the pattern of square shapes in the layout 602 of FIG. 6. At 1306, the method 1300 includes generating a SRAF pattern based on the target pattern. One example of a SRAF pattern is the SRAF pattern 603 of FIG. 6. At 1308, the method 1300 includes generating a main pattern after generating the SRAF pattern. One example of a main pattern is the main pattern 605 of FIG. 6. At 1310, the method 1300 includes placing the SRAF pattern and the main pattern on the blank mask after generating the SRAF pattern.

Embodiments of the present disclosure generate the pattern layout for a photolithography mask in an effective and efficient manner. The SRAF pattern is generated from a blank mask layout without a previously generated main pattern. Instead, the SRAF pattern is based on a target pattern corresponding to a pattern desired to be formed on a device. The SRAF pattern is generated in iterations. The gradient of a cost function is monitored between iterations until a SRAF pattern has been found that results in optimum function. The main pattern of the mask can be formed simultaneously with the SRAF pattern or after formation of the SRAF pattern. OPC fine-tuning can then be performed. After the SRAF pattern and main patterns have been determined, the photolithography mask can be formed including the determined SRAF and main patterns. This process results in higher quality photolithography masks. This further results in integrated circuits with higher yields and fewer defects.

In some embodiments, a method for preparing a mask for use in a photolithographic patterning of a layer on a substrate includes setting a blank mask and determining a target pattern, the target pattern corresponding to a pattern to be formed in the layer on the substrate. The method includes generating a sub-resolution assist feature (SRAF) pattern based on the target pattern, generating a main pattern based on the target pattern, and placing the SRAF pattern and the main pattern on the blank mask, after generating the SRAF pattern.

In one embodiment, a system includes a light source, a photolithography mask having a sub-resolution assist feature (SRAF) pattern, and one or more controllers. The one or more controllers are configured to generate the SRAF pattern by an iteration process, form the SRAF pattern on a blank mask, and in response, generate the photolithography mask, form a target pattern on the substrate by exposing the light source on the photolithography mask.

In one embodiment, a method includes forming a device by a photolithography process. The process includes exposing a photolithography mask by a light source and forming a target pattern on a substrate of the device in response to the exposing the photolithography mask. The photolithography mask has sub-resolution assist feature (SRAF) patterns and main patterns that are formed on the photolithography mask by determining the target pattern, generating a light transmission pattern based on the target pattern, generating the SRAF patterns and main patterns based on an iteration process of the light transmission pattern, and forming the SRAF patterns and main patterns on a blank mask, after generating the SRAF pattern.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method comprising:
preparing a mask for use in a photolithographic patterning of a layer on a substrate, the preparing the mask including:
generating a blank mask layout;
determining a target pattern, the target pattern corresponding to a pattern to be formed in the layer on the substrate;
generating a sub-resolution assist feature (SRAF) pattern from the blank mask layout based on the target pattern;
generating a main pattern based on the target pattern; and
placing the SRAF pattern and the main pattern on the blank mask layout, after generating the SRAF pattern.

2. The method of claim 1 wherein the generating the SRAF pattern is based on an iteration process.

3. The method of claim 2 wherein the iteration process generates the SRAF pattern and the main pattern simultaneously.

4. The method of claim 2 wherein the generating the SRAF pattern includes estimating the SRAF pattern from peaks of optical transmission after a subset of the iteration process, and wherein the peaks of optical transmission are determined by a simulation method.

5. The method of claim 2 wherein the iteration process is based on a gradient function for maximizing an image slope corresponding to the target pattern.

6. The method of claim 2 wherein the iteration process includes generating a mask polygon and the main pattern after completion of the iteration process.

7. The method of claim 6 wherein the main pattern is circle shaped.

8. The method of claim 1 wherein the layer on the substrate is a layer of photoresist.

9. A system comprising:
a light source;
a photolithography mask having a sub-resolution assist feature (SRAF) pattern; and
one or more controller configured to:
generate the SRAF pattern by an iteration process;
impose the SRAF pattern on a blank mask;
generate the photolithography mask based on the SRAF pattern; and
form a target pattern on a substrate by irradiating the photolithography mask with the light source.

10. The system of claim 9 wherein the controller configured to generate a main pattern based on the target pattern.

11. The system of claim 10 wherein the iteration process generates the SRAF pattern and the main pattern simultaneously.

12. The system of claim 11 wherein the controller configured to form the SRAF pattern and the main pattern on the blank mask after a subset of the iteration process.

13. The system of claim 11 wherein the controller configured to form the SRAF pattern and the main pattern on the blank mask after completion of the iteration process, the SRAF pattern is polygon shaped, and a shape of the main pattern is the same as a shape of the target pattern.

14. The system of claim 9 wherein the iteration process is based on a gradient function for maximizing an image slope corresponding to the target pattern.

15. A method comprising:
forming a device by a photolithography process, the photolithography process including:
forming a target pattern on a substrate of the device by exposing a photolithography mask to light from a light source, the photolithography mask having sub-resolution assist feature (SRAF) patterns and main patterns that are formed on the photolithography mask by:
determining the target pattern;
generating a light transmission pattern based on the target pattern;
generating the SRAF patterns and the main patterns based on an iteration process of the light transmission pattern; and
forming the SRAF patterns and the main patterns on a blank mask, after generating the SRAF pattern.

16. The method of claim 15 wherein the SRAF patterns are polygon shaped, and a shape of the main patterns is the same as a shape of the target pattern.

17. The method of claim 15 wherein the generating the SRAF patterns includes estimating the SRAF patterns from peaks of the light transmission pattern after a subset of the iteration process.

18. The method of claim 17 wherein after the subset of the iteration process the main patterns having different shaped than the target pattern.

19. The method of claim 15 wherein the iteration process is based on a gradient function for maximizing an image slope corresponding to the target pattern.

20. The method of claim 15 wherein the iteration process optimizes the SRAF patterns and the main patterns simultaneously.
